(19) United States
(12) Patent Application Publication
(10) Pub. No.: US 2024/0004786 A1
(43) Pub. Date: Jan. 4, 2024

(54) ALLOCATING MEMORY FOR PROCESSING-IN-MEMORY (PIM) DEVICES

(71) Applicant: ADVANCED MICRO DEVICES, INC., SANTA CLARA, CA (US)

(72) Inventors: VIGNESH ADHINARAYANAN, AUSTIN, TX (US); MAHZABEEN ISLAM, AUSTIN, TX (US); JAGADISH B. KOTRA, AUSTIN, TX (US); SERGEY BLAGODUROV, BELLEVUE, WA (US)

(21) Appl. No.: 17/855,157

(22) Filed: Jun. 30, 2022

(51) Int. Cl. G06F 3/06

(52) U.S. Cl. CPC G06F 3/0647; G06F 3/0604; G06F 3/0683

(57) ABSTRACT

Allocating memory for processing-in-memory (PIM) devices, including: allocating, in a first Dynamic Random Access Memory (DRAM) sub-array, a first data structure beginning in a first grain of the DRAM; allocating, in a second DRAM sub-array, a second data structure beginning in a second grain of the DRAM; and wherein the second DRAM sub-array is different from the first DRAM sub-array and the second grain is different from the first grain.

### BACKGROUND

Processing-in-memory (PIM) allows for data stored in Random Access Memory (RAM) to be acted upon directly in RAM. Memory modules that support PIM include some amount of general purpose registers (GPRs) per bank to assist in PIM operations. For example, some amount of data stored in RAM will be loaded into GPRs before being input from the GPRs into other logic (e.g., an arithmetic logic unit (ALU)). Where the amount of data in any data structure used in a PIM operation exceeds the amount of data available to be stored in the GPRs, in some implementations, multiple rows in RAM will need to be opened and closed in order to perform the PIM operation. This introduces a row activation delay, negatively affecting performance.

### BRIEF DESCRIPTION OF THE DRAWINGS

FIG. 1A is an example memory layout for PIM devices.

FIG. 1B is an example memory layout for PIM devices.

FIG. 2 is a block diagram of an example apparatus for allocating memory for processing-in-memory (PIM) devices according to some implementations.

FIG. 3A is a block diagram of an example memory bank for allocating memory for processing-in-memory (PIM) devices according to some implementations.

FIG. 3B is a block diagram of an example memory bank for allocating memory for processing-in-memory (PIM) devices according to some implementations.

FIG. 4A is an example wiring diagram for allocating memory for processing-in-memory (PIM) devices according to some implementations.

FIG. 4B is an example wiring diagram for allocating memory for processing-in-memory (PIM) devices according to some implementations.

FIG. 5 is an example memory layout for allocating memory for processing-in-memory (PIM) devices according to some implementations.

FIG. 6 is an example timing diagram for allocating memory for processing-in-memory (PIM) devices according to some implementations.

FIG. 7A is an example memory addressing scheme for allocating memory for processing-in-memory (PIM) devices according to some implementations.

FIG. 7B is an example memory addressing scheme for allocating memory for processing-in-memory (PIM) devices according to some implementations.

FIG. 8 is a flowchart of an example method for allocating memory for processing-in-memory (PIM) devices according to some implementations.

FIG. 9 is a flowchart of another example method for allocating memory for processing-in-memory (PIM) devices according to some implementations.

FIG. 10 is a flowchart of another example method for allocating memory for processing-in-memory (PIM) devices according to some implementations.

FIG. 11 is a flowchart of another example method for allocating memory for processing-in-memory (PIM) devices according to some implementations.

### DETAILED DESCRIPTION

Processing-in-memory (PIM) allows for data stored in Random Access Memory (RAM) to be acted upon directly in RAM. Memory modules that support PIM include some amount of general purpose registers (GPRs) per bank to assist in PIM operations. For example, some amount of data stored in RAM will be loaded into GPRs before being input from the GPRs into other logic (e.g., an arithmetic logic unit (ALU)). Where the amount of data in any data structure used in a PIM operation exceeds the amount of data available to be stored in the GPRs, in some implementations, multiple rows in RAM will need to be opened and closed in order to perform the PIM operation.

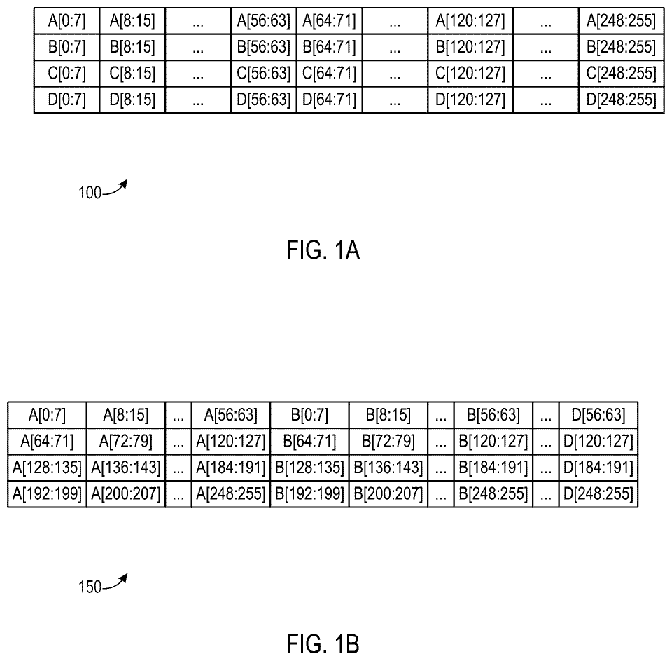

Consider an example of a PIM integer vector add operation C[ ]=A[ ]+B[ ], where values of a same index in vectors A[ ] and B[ ] are added together and stored in a same index of vector C[ ]. Further assume a Dynamic Random Access Memory (DRAM) row size of one kilobyte and an integer size of 32 bits, meaning that each DRAM row is capable of holding 256 vector entries. Further assume that the memory module includes eight GPRs of 256 bits each, meaning that the GPRs are capable of storing sixty-four 32-bit integer vector entries. Using the example memory layout 100 of FIG. 1A, each vector is stored in a different row of DRAM. To perform this example vector add operation, a first row storing A[ ] is opened and sixty four integer values are loaded into the GPRs. The row storing A[ ] is then closed and then a second row storing B[ ] is opened. Sixty-four integer values are loaded from the second row, and provided to an ALU with the GPRs in order to calculate the first sixty-four values for the vector C[ ]. The row storing B[ ] is then closed and a third row storing C[ ] is opened in order to allow these first sixty-four values to be stored in C[ ]. The row storing C[ ] is then closed and the first row storing A[ ] is reopened, whereby the process repeats for the next set of sixty-four values.

This repeated opening and closing of rows results in row cycle time (t_{RC}) penalties for each row activation. Assume the following memory timing constraints: t_{RC}=47 ns, row-to-row delay long (t_{RRDL})=2 ns, column-to-column delay long (t_{CCDL})=2 ns, precharge time (t_{RP})=14 ns, and row-to-column delay (t_{RRCD})=14 ns. As referred to herein, an atom is the smallest amount of data that can be transferred to or from DRAM, which, in this example, is equal to 32 bytes. Eight atoms are fetched from array A[ ] in 8*t_{CCDL} time (i.e., 8*2 ns=16 ns) before the activated row must be precharged and a new row activated to fetch array B[ ] as the register capacity is limited. This means between two activates (i.e., t_{RC}=47 ns), the DRAM bank is utilized only for 16 ns, leading to a bank utilization of 34% for vector add. In contrast, performing a reduction of A[ ] (e.g., an operation acting only on A[ ] such as a summation) keeps the bank busy for 32*2 ns=64 ns (i.e., atoms in row*t_{CCDL}) per activate-access-precharge cycle (14 ns+64 ns+14 ns) resulting in a bank utilization of 69.5%.

An existing solution for reducing this t_{RC} penalty allocates vector elements from different vectors to the same DRAM row, such as in the memory layout 150 of FIG. 1B. Though this memory layout 150 results in a performance increase for PIM operations using multiple data structures (e.g., multiple vectors), it causes a performance decrease for reduction operations acting only on a single data structure (e.g., a single vector). In this example, 64 elements each from arrays A, B, and C (or 8*3=24 HBM atoms) are accessed before opening and closing a row, keeping the device busy for (8*3)*2 ns=48 ns before paying an t_{RP}+t_{RRCD}=14 ns+14 ns=28 ns penalty (i.e., resource utilization=63.2% for vector add). However, when performing a reduction on A[ ], a new DRAM row must be opened for every 64 elements of A[ ]. That is, the device is busy for 8*t_{CCDL}=8*2 ns=16 ns before the current row is closed and a new row opened (47 ns after the first row was opened). The device is kept busy for only 16 ns out of every 47 ns which results in a bank utilization of 34% for reduction operations.

To that end, the present specification sets forth various implementations for allocating memory for processing-in-memory (PIM) devices. In some implementations, a method of allocating memory for processing-in-memory (PIM) devices includes: allocating a first data structure in a first Dynamic Random Access Memory (DRAM) sub-array beginning in a first grain of the DRAM and allocating a second data structure beginning in a second grain of the DRAM in a second DRAM sub-array. In such an implementation, the second DRAM sub-array is different from the first DRAM sub-array and the second grain is different from the first grain.

In some implementations, the second DRAM sub-array is adjacent to the first DRAM sub-array and the second grain is adjacent to the first grain. In some implementations, each entry of the second data structure is stored in a DRAM grain adjacent to another DRAM grain storing a corresponding entry of the first data structure having a same index. In some implementations, the method also includes performing a processing-in-memory (PIM) operation based on the first data structure and the second data structure. In some implementations, performing the PIM operation includes opening two or more DRAM rows in different grains concurrently. In some implementations, the method also includes performing a reduction operation based on the first data structure. In some implementations, allocating the first data structure includes storing a first table entry including a first identifier for the first data structure and wherein allocating the second data structure includes storing a second table entry including a second identifier for the second data structure. In some implementations, the table includes a page table or a page attribute table.

The present specification also describes various implementations of an apparatus for allocating memory for processing-in-memory (PIM) devices. Such an apparatus includes: Dynamic Random Access Memory (DRAM), a DRAM controller operatively coupled to the DRAM, and a processor operatively coupled to the DRAM controller. The processor is configure to perform: allocating, in a first Dynamic Random Access Memory (DRAM) sub-array, a first data structure beginning in a first grain of the DRAM, allocating, in a second DRAM sub-array, a second data structure beginning in a second grain of the DRAM. In such an implementation, the second DRAM sub-array is different from the first DRAM sub-array and the second grain is different from the first grain.

In some implementations, the second DRAM sub-array is adjacent to the first DRAM sub-array and the second grain is adjacent to the first grain. In some implementations, each entry of the second data structure is stored in a DRAM grain adjacent to another DRAM grain storing a corresponding entry of the first data structure having a same index. In some implementations, the DRAM controller performs a processing-in-memory (PIM) operation based on the first data structure and the second data structure. In some implementations, performing the PIM operation includes opening two or more DRAM rows in different grains concurrently. In some implementations, the DRAM controller performs a reduction operation based on the first data structure. In some implementations, allocating the first data structure includes storing a first table entry including a first identifier for the first data structure and wherein allocating the second data structure includes storing a second table entry including a second identifier for the second data structure. In some implementations, the table includes a page table or a page attribute table.

Also described in this specification are various implementations of a computer program product for allocating memory for processing-in-memory (PIM) devices. Such a computer program product is disposed upon a non-transitory computer readable medium and includes computer program instructions for allocating memory for processing-in-memory (PIM) devices that, when executed, cause a computer system to perform steps including: allocating, in a first Dynamic Random Access Memory (DRAM) sub-array, a first data structure beginning in a first grain of the DRAM, allocating, in a second DRAM sub-array, a second data structure beginning in a second grain of the DRAM, and where the second DRAM sub-array is different from the first DRAM sub-array and the second grain is different from the first grain.

In some implementations, each entry of the second data structure is stored in a DRAM grain adjacent to another DRAM grain storing a corresponding entry of the first data structure having a same index. In some implementations, the steps further include performing a processing-in-memory (PIM) operation based on the first data structure and the second data structure. In some implementations, performing the PIM operation includes opening two or more DRAM rows in different grains concurrently. In some implementations, the steps further include performing a reduction operation based on the first data structure. In some implementations, allocating the first data structure includes storing a first table entry including a first identifier for the first data structure and wherein allocating the second data structure includes storing a second table entry including a second identifier for the second data structure.

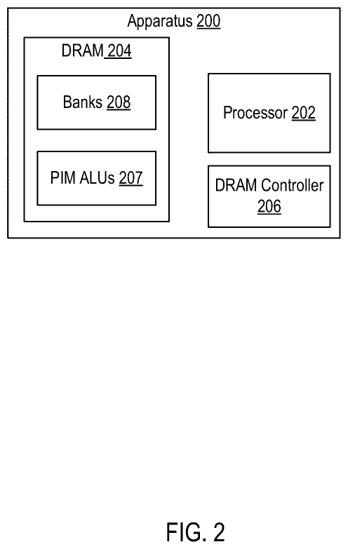

FIG. 2 is a block diagram of a non-limiting example apparatus 200. The example apparatus 200 can be implemented in a variety of computing devices, including mobile devices, personal computers, peripheral hardware components, gaming devices, set-top boxes, and the like. The apparatus 200 includes a processor 202 such as a central processing unit (CPU) or other processor 202 as can be appreciated. The apparatus 200 also includes DRAM 204 and a DRAM controller 206. The DRAM controller 206 receives memory operations (e.g., from the processor 202) for execution on application to the DRAM 204.

The DRAM 204 includes one or more modules of DRAM 204. Although the following discussion describes the use of DRAM 204, one skilled in the art will appreciate that, in some implementations, other types of RAM are also used. Each module of DRAM 204 includes one or more banks 208. The banks 208 are a logical subunit of memory that includes multiple rows and columns of cells into which a data value (e.g., a bit) is stored. Each module of DRAM 204 also includes one or more processing-in-memory arithmetic logic units (PIM ALUs) 207 that perform processing-in-memory functions on data stored in the banks 208.

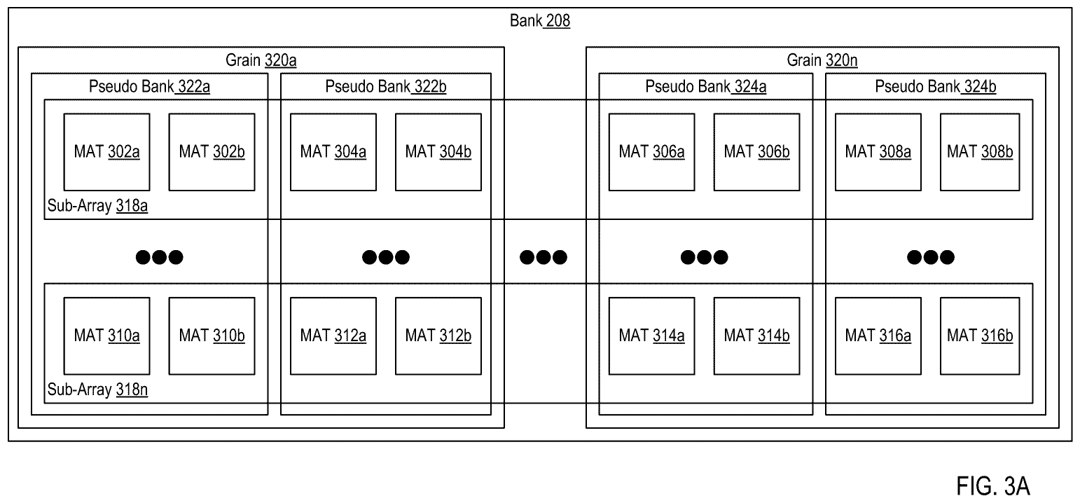

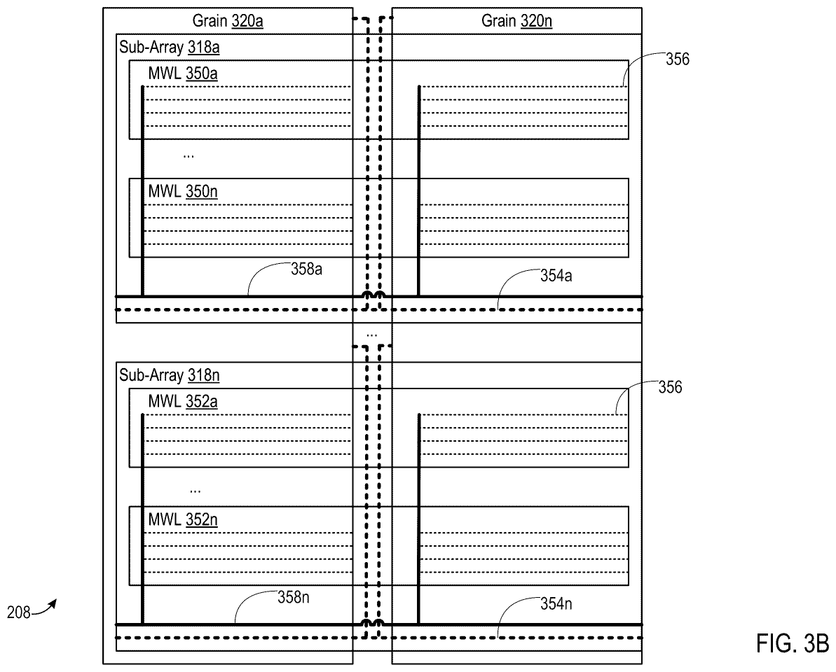

An example organization of banks 208 is shown in FIG. 3A. Each bank 208 includes multiple matrices (MATs) 302a, 302b, 304a, 304b, 306a, 306b, 308a, 308b, 310a, 310b, 312a, 312b, 314a, 314b, 316a, 316b, collectively referred to as MATs 302a-316b. Each MAT 302a-316b is a two-dimensional array (e.g., a matrix) of cells, with each cell storing a particular bit value. As an example, in some implementations, each MAT 302a-316b includes a 512×512 matrix of cells having 512 rows of 512 columns. The MATs 302a-316b each belong to a particular sub-array 318a-n.

In contrast to existing solutions, each bank 208 is further subdivided into multiple grains 320a-n. As an example, in some implementations, each bank 208 is divided into four grains 320a-n. As described herein, grains 320a-n are logical subdivisions of banks 208 that can be activated concurrently. Here, a grain 320a-n is a logical grouping of MATs 302a-316b including a subset of MATs 302a-316b across sub-arrays 318a-n. In some implementations, each grain 320a-n is further logically subdivided into pseudo banks 322a, 322b, 324a, 324b.

As shown in FIG. 3B, the bank 208 is divided into grains 320a-n by segmenting a master wordline (MWL) 350a-n, 352a-n used to access particular rows in the bank 208. Thus, in contrast to existing solutions where asserting the MWL 350a-352n would activate a row in each MAT 302a-316b in a same sub-array 318a-n, asserting the segmented MWL 350a-352n activates only those rows for each MAT 302a-316b in a same sub-array 318a-n and in a same grain 320a-n. Thus, where a bank 208 implements four grains 320a-n, the effective row size is reduced to one-quarter of a row size where grains 320a-n are not implemented. This reduced row size also reduces activation energy and eliminating four activate window (t_{FAW}) constraints.

The MWL 350a-352n is segmented by adding in a grain selection line 354a-n for selecting a particular grain 320a-n. Although FIG. 3B depicts the grain selection lines 354a-n as a single line, one skilled in the art will appreciate that this is for illustrative purposes and that, in some implementations, each sub-array 318a-n may include multiple grain selection lines 354a-n each for selecting a particular grain 320a-n. The grain selection (GrSel) lines 354a-n are shared by all rows within a sub-array 318a-n. In some implementations, each MWL 350a-352n is connected to multiple local word lines (LWLs) 356 with each LWL 356 driving a particular row. Thus, each MWL 350a-352n drives a number of rows within a sub-array 318a-n equal to the number of connected LWLs 356. To activate a single row, an LWL 356 is activated via an LWL selection line (LWLSel) 358a-n shared by all rows within a sub-array 318a-n.

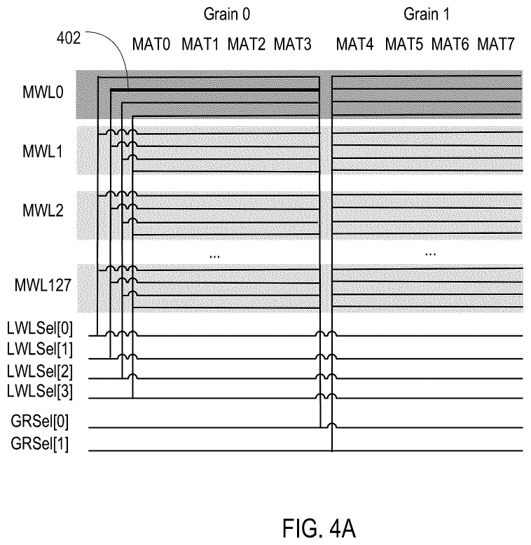

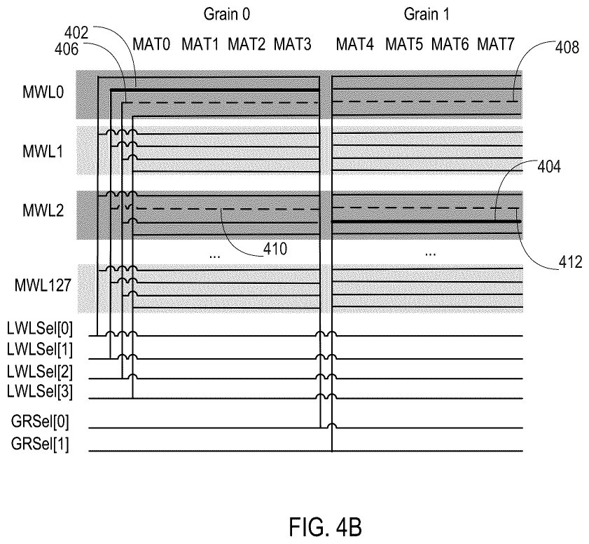

Because activating a row within a same sub-array 318a-n requires activating both a MWL 340a-352n and a LWL using a LWLSel shared across MWLs 350a-352n, the only scenario where two rows within a sub-array 318a-n can be activated together is when the MWL and the LWLSel being activated are the same across grains. Otherwise, activating a first row in a first grain that has a different MWL and/or LWLSel than an active second row in a second grain will cause additional rows to be activated in the second grain. This is illustrated in FIGS. 4A and 4B.

FIG. 4A shows an example activation for sub-array 318a-n with two grains and eight MATs for clarity and brevity. Here, an activation is issued for a row[1] of grain[0], shown here as row 402. To perform this activation, MWL[0] is driven as shown by the darker shading of MWL[0]. GRSel[0] and LWLSel[1] are also driven so as to activate grain[0] row[1], as shown by the boldened row 402.

Turning now to FIG. 4B, assume that row[10] of grain[1], shown here as row 404, is to be activated concurrently with row[1] of grain[0]. Here, row 404 corresponds to row[2] of MWL[2]. Accordingly, to activate row 404, MWL2 is driven as shown by the now darker shading of MWL[2]. GRSel[1] and LWLSel[2] are also driven. Because activating row 404 causes LWLSel[2] to also be driven, row 406 (for the still active MWL[0] and LWLSel[2] in grain[0]) and row 408 (for MWL[0] and LWLSel[2] in grain[1]) are also activated, as shown using dashes. Similarly, as row 402 is still active, activating row 404 would also cause row 410 and row 412 (for active MWL[2] and LWLSel[1] in grain[0] and grain[1], respectively) to be activated. In order to prevent the unintentional activation of rows (e.g., rows 406,408,410,412 as shown in FIG. 4B), two rows within a sub-array can only be activated together when the MWL and LWLSel being activated are the same across grains. Activates are able to be issued across grains 320a-n where the activated rows belong to different sub-arrays 318a-n.

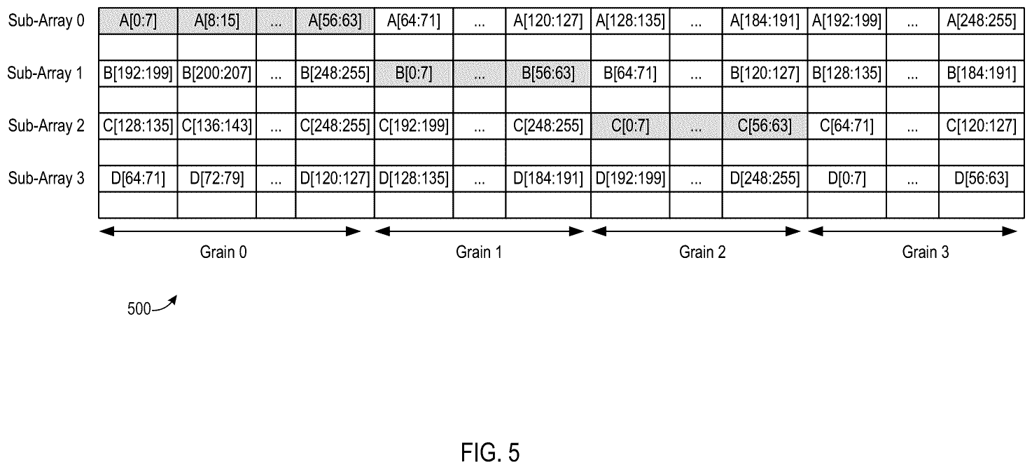

Given this example memory implementation of FIG. 3A, data structures are allocated and mapped in DRAM 204 such that, where data structures are to be accessed together (e.g., for a PIM operation), elements of each data structure allocated such that the start of each data structure is offset to begin at a different grain 320a-n. This is shown in the example memory layout 500 of FIG. 5.

The example memory layout 500 shows arrays A[ ], B[ ], and C[ ]. The inclusion of array D[ ] is illustrative and is not described in the following example of a PIM operation using the memory layout 500. As shown, the example memory layout 500 shows four sub-arrays 318a-n and four grains 320a-n. Each array A[ ], B[ ], and C[ ] has a starting offset in different grains 320a-n and sub-arrays 318a-n. For example, A[ ] is stored in sub-array 0 beginning at grain 0, B[ ] is stored in sub-array 1 beginning at grain 1, and C[ ] is stored in sub-array 2 beginning at grain 2.

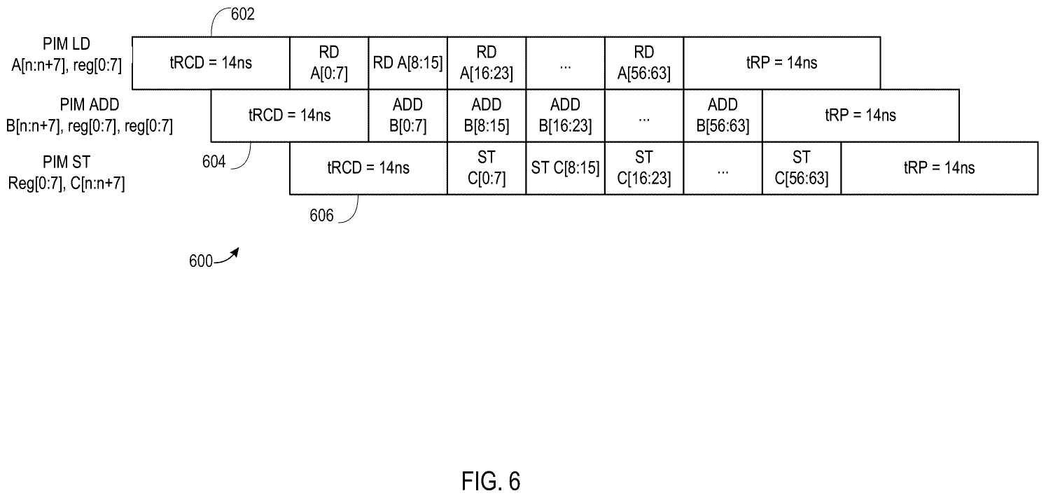

As described above, rows in different sub-arrays 318a-n are able to be activated together provided they are stored in different grains 320a-n. In other words, rows for each data structure (arrays A[ ], B[ ], and C[ ]) are able to be open concurrently in order to perform a PIM operation. As shown in the timing diagram 600 of FIG. 6, rows containing B[ ] are activated after those containing A[ ] without incurring a t_{RC} penalty. For example, at point 602, array A[ ] is opened so as to allow the subsequent read operations on array A[ ] to be performed. Here, opening array A[ ] incurs a t_{rcd} penalty of 14 ns. At point 604, array B[ ] is opened, also incurring a t_{rcd} penalty of 14 ns. As A[ ] and B[ ] are stored in different sub-arrays 318a-n, existing solutions would necessitate that the row for A[ ] would need to be closed before opening the row for B[ ], which would incur a t_{RC} penalty. In contrast, as the portions of A[ ] and B[ ] to be added together are stored in different grains 320a-n, their respective rows may be activated together. As they may be activated together, there is no t_{RC} penalty associated with closing one row and activating another. Similarly, at point 606 where array C[ ] is opened, this action incurs a t_{rcd} penalty of 14 ns but no t_{RC} penalty for closing B[ ] as the rows of C[ ] to be activated are stored in different grains than A[ ] or B[ ]. Turning back to FIG. 5, for a reduction operation (e.g., operating only on array A[ ] in sub array 1), accesses to successive elements in A[ ] result in addresses that share the same MWL and LWLSel across grains, allowing the elements of A[ ] to be accessed without incurring a t_{RC} penalty.

In some implementations, memory allocations such as those shown in FIG. 5 are performed based on programmer provided hints or pragmas included in code to be compiled. A pragma is a portion of text that itself is not compiled but that instructs a compiler how to process or compile a subsequently occurring line of code. A compiler identifying these pragmas will generate memory allocation code that will allocate data structures such as those set forth in FIG. 5. As an example, pragmas indicating that particular data structures will be allocated together for a PIM operation will be allocated in different sub-arrays 318a-n beginning in different grains. For example, refer to the following portion of example pseudo-code:
#pragma group one, two
pim malloc(&A, nbytes)
#pragma group one
pim malloc(&B, nbytes)
#pragma group one
pim malloc(&C, nbytes)
#pragma group two
pim malloc(&D, nbytes)
#pragma group two
pim malloc(&E, nbytes)

In this example, the pragmas are indicated by lines including the “#” character. Here, the pragma indicates that A will be accessed in two groups, with B and C also included in a first group and C and D included in a second group. N-bytes of memory (e.g., shown by the “nbytes” operand) will be allocated for each data structure.

In some implementations, the compiler will determine, for each data structure A-E, an identifier. In some implementations, the identifier is included as a parameter in a memory allocation function or in a pragma preceding the memory allocation function. In some implementations, where an identifier is not explicitly present, the compiler will determine the identifier in order to avoid access skews as will be described below.

On execution of the memory allocation function generated by the compiler, in some implementations, the identifier is included in a table entry corresponding to the allocated memory. For example, in some implementations, the identifier is included in a page table entry for the allocated memory for a given data structure. In some implementations, the identifier is included in a page attribute table entry for the given data structure.

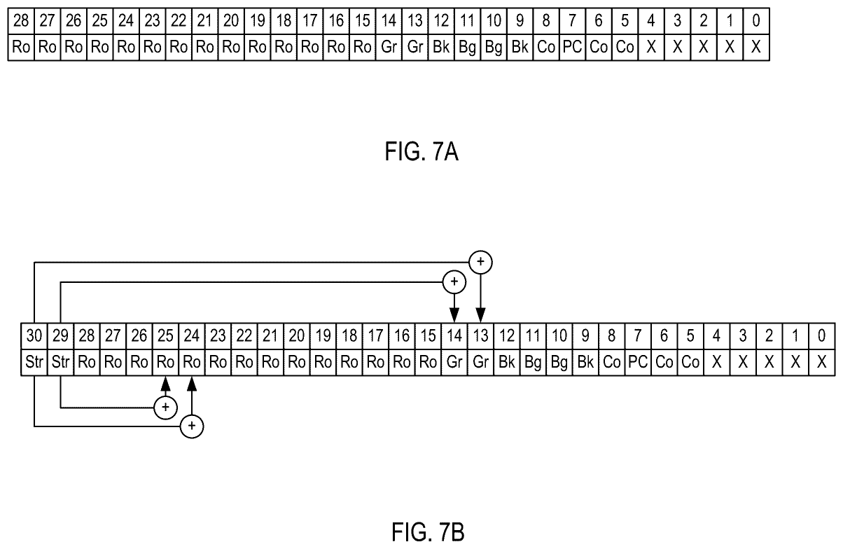

When an operation targeting an allocated data structure is executed (e.g., a load/store operation or a PIM instruction), an address translation mechanism (e.g., the operating system) accesses a table entry for the data structure. For example, a page table entry for the data structure is accessed. The identifier is combined with a physical address also stored in the table entry to generate an address submitted to the DRAM controller 206 to perform the operation. As an example, one or more bits of the identifier are combined with one or more bits of an address using an exclusive-OR (XOR) operation to generate an address submitted to the DRAM controller 206. For example, assume the address bit mapping 700 of FIG. 7A. The bits at indexes 16-18 identify a particular DRAM 204 row and the bits at indexes 13-14 identify a particular grain 320a-n. As shown in FIG. 7B, identifier bits shown at indexes 29-30 are combined via an XOR operation with the row- and grain-identifying bits. This ensures that the entries having the same indexes in different data structures will fall into different grains 320a-b and different sub-arrays 318a-n in the same bank 208. One skilled in the art will appreciate that, in some implementations, functions other than XOR that produce a unique 1:1 mapping between the input and output are used, such as a rotate operation that rotates address bits by the identifier.

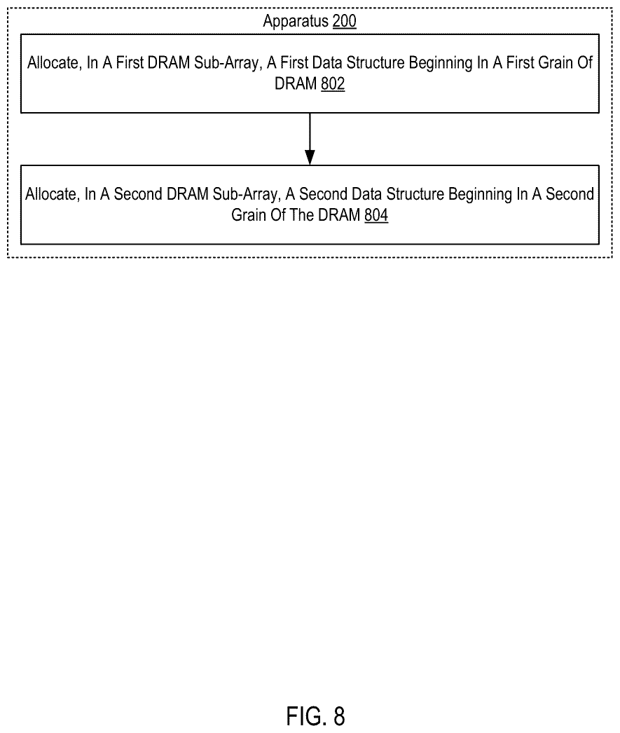

The approaches described above for allocating memory for processing-in-memory (PIM) devices are also described as methods in the flowcharts of FIGS. 8-11. Accordingly, for further explanation, FIG. 8 sets forth a flow chart illustrating an example method for allocating memory for processing-in-memory (PIM) devices according to some implementations of the present disclosure. The method of FIG. 8 is implemented, for example, in an apparatus 200. The method of FIG. 8 includes allocating 802, in a first DRAM sub-array 318a-n, a first data structure beginning in a first grain 320a-n of DRAM 204. The first data structure includes, for example, a vector, an array, or another data structure including a plurality of entries that are referenced or accessible via an index. The first data structure begins in a first grain 320a-n of DRAM 204 in that a portion of memory corresponding to a first index of the data structure (e.g., index “0”) is stored beginning at a first grain 320a-n of the DRAM 204. As described herein, a grain 320a-n is a subdivision of DRAM 204 including portions of each sub-array 318a-n of DRAM 204. For example, each sub-array 318a-n of DRAM 204 includes a portion of memory in one of multiple grains 320a-n.

The method of FIG. 8 also includes allocating 804, in a second DRAM sub-array 318a-n, a second data structure beginning in a second grain 320a-n of the DRAM 204. The second data structure is a similar data structure to the first data structure (e.g., a vector, an array, and the like). In some implementations, the second data structure is of a same size or a same number of entries as the first data structure. The second data structure begins in a second grain 320a-n that is different from the first grain 320a-n. As an example, the second data structure begins in a second grain 320a-n that is sequentially adjacent to the first grain 320a-n. For example, where the first data structure begins at grain “0,” the second data structure begins at grain “1.”

In some implementations, the first data structure and second data structure are allocated in different sub-arrays 318a-n. The sub-array 318a-n storing the second data structure is different than the sub-array 318a-n storing the first data structure. As an example, the sub-array 318a-n storing the second data structure is sequentially adjacent to the sub-array 318a-n storing the first data structure. For example, where the first data structure is stored at sub-array “0,” the second data structure is stored in sub-array “1.” Thus, the first and second data structures are allocated in different sub-arrays 318a-n beginning in different grains 320a-n.

In some implementations, allocating the first data structure and second data structure includes reserving or allocating some portion of memory for each data structure and storing entries indicating the allocated memory in a table, such as a page table. The first and second data structures are considered “allocated” in that some portion of memory is reserved for each data structure, independent of whether or not the data structures are initialized (e.g., with some value is stored in the allocated portions of memory).

In some implementations, the first and second data structures are allocated in response to an executable command or operation indicating that the first and second data structures should be allocated in DRAM 204, thereby allowing the first and second data structures to be subject to PIM operations or reductions directly in memory.

One skilled in the art will appreciate that, in some implementations, other data structures will also be allocated in DRAM 204. For example, in order to perform a three-vector PIM operation, a third data structure will be allocated in DRAM 204. One skilled in the art will appreciate that, in such an implementation, the third data structure is allocated in another sub-array 318a-n different from the sub-arrays 318a-n storing the first and second data structures. One skilled in the art will also appreciate that, in such an implementation, the third data structure will be allocated to begin in another grain 320a-n different from the grains 320a-n at which the first and second data structure begin. As an example, the third data structure will begin at a grain 320a-n sequentially after the grain 320a-n at which the second data structure begins.

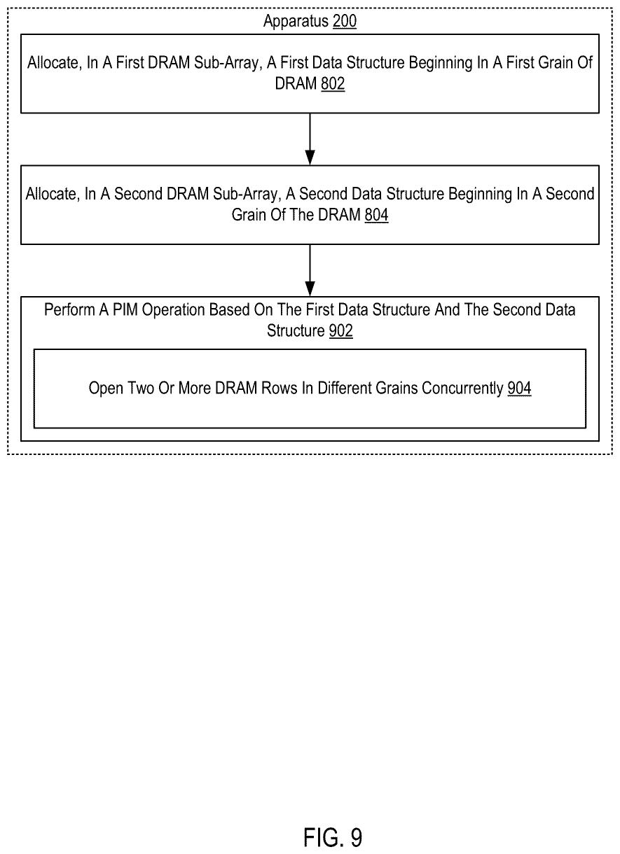

For further explanation, FIG. 9 sets forth a flow chart illustrating another example method for allocating memory for processing-in-memory (PIM) devices according to some implementations of the present disclosure. The method of FIG. 9 is similar to FIG. 8, differing in that FIG. 9 also includes performing 902 a PIM operation based on the first data structure and the second data structure. As an example, the PIM operation includes the first data structure and the second data structure as operands or parameters (e.g., a vector add operation, a vector subtraction operation, and the like). For example, a DRAM controller 206 issues a command to a DRAM 204 bank 208 indicating a type of PIM operation and identifying the first and second data structures, and potentially other data structures serving as parameters or operands).

In some implementations, performing 902 the PIM operation includes opening 904 two or more DRAM rows in different grains 320a-n concurrently. As example, a first row in a first grain 320a-n (e.g., corresponding to the first data structure) is open concurrent to a second row in a second grain 320a-n (e.g., corresponding to the second data structure). A MWL is segmented by adding in a grain selection line for each grain 320a-n. The grain selection (GrSel) lines are shared by all rows within a sub-array 318a-n. Thus, in some implementations, rows within a same sub-array 318a-n can only be activated sequentially. In some implementations, each MWL is connected to multiple local word lines (LWLs). Thus, each MWL drives a number of rows within a sub-array 318a-n equal to the number of connected LWLs. To activate a single row, an LWL is activated via an LWL selection line (LWLSel) shared by all rows within a sub-array 318a-n. This allows for rows in different sub-arrays 318a-n to be activated provided they are in different grains 320a-n.

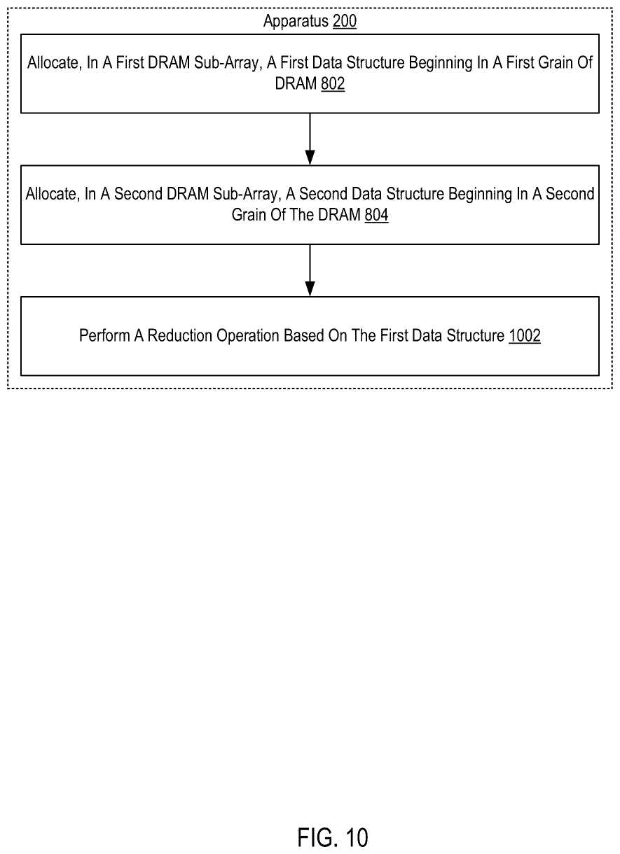

For further explanation, FIG. 10 sets forth a flow chart illustrating another example method for allocating memory for processing-in-memory (PIM) devices according to some implementations of the present disclosure. The method of FIG. 10 is similar to FIG. 8, differing in that FIG. 10 also includes performing 1002 a reduction operation based on the first data structure. A reduction operation is an operation applied to a single data structure (e.g., the first data structure). For example, a reduction operation calculates an aggregate value (e.g., average, min, max, and the like) based on each value in a data structure. Using the memory layout described herein (e.g., FIG. 5), a data structure such as the first data structure is allocated across multiple rows in the same sub-array 318a-n, with each row being stored in a different grain 320a-n. In order to perform the reduction operation, each row storing portions of the first data structure must be activated.

As set forth above, a MWL is segmented by adding in a grain selection line for each grain 320a-n. The grain selection (GrSel) lines are shared by all rows within a sub-array 318a-n. This requires that rows within a same sub-array 318a-n to be activated sequentially. The reduction operation is performed on the first data structure by sequentially activating each row that stores the first data structure. Due to the memory layout described herein, these rows are activated sequentially without incurring a t_{RC} penalty. Thus, the same memory layout allows for improved efficiency in PIM operations, such as those described in FIG. 9, without incurring any additional penalties when performing reduction operations, as described in FIG. 10.

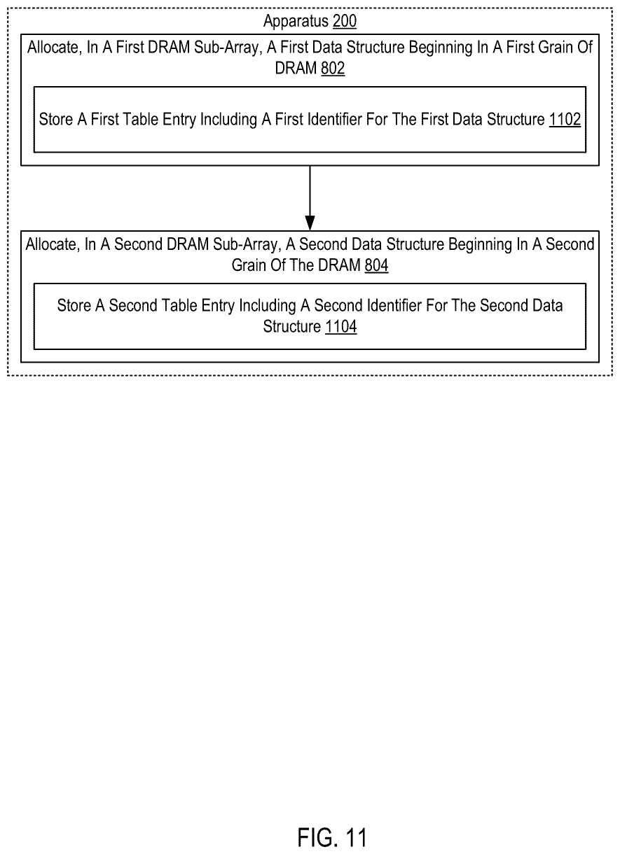

For further explanation, FIG. 11 sets forth a flow chart illustrating another example method for allocating memory for processing-in-memory (PIM) devices according to some implementations of the present disclosure. The method of FIG. 11 is similar to FIG. 8, differing in that allocating 802, in a first DRAM sub-array 318a-n, a first data structure beginning in a first grain 320a-n of DRAM 204 includes storing 1102 a first table entry including a first identifier for the first data structure, and in that allocating 804, in a second DRAM sub-array 318a-n, a second data structure beginning in a second grain 320a-n of DRAM 204 includes storing 1104 a second table entry including a second identifier for the second data structure.

In some implementations, a compiler will determine the identifiers for the first and second data structures. In some implementations, the identifier is included as a parameter in a memory allocation function or in a pragma preceding the memory allocation function. Such memory allocation functions, when executed, cause the allocation of memory for the first and second data structures. In some implementations, where an identifier is not explicitly present, the compiler will determine the identifier in order to avoid access skews as will be described below. In some implementations, the first and second table entries include entries in a page table. In some implementations, the first and second table entries include entries in a page attribute table entry.

When an operation targeting an allocated data structure is executed (e.g., a load/store operation or a PIM instruction), an address translation mechanism (e.g., the operating system) accesses a table entry for the data structure. For example, a page table entry for the data structure is accessed. The identifier is combined with a physical address also stored in the table entry to generate an address submitted to the DRAM controller 206 to perform the operation. As an example, one or more bits of the identifier are combined with one or more bits of an address using an exclusive-OR (XOR) operation to generate an address submitted to the DRAM controller 206. This ensures that the entries having the same indexes in different data structures will fall into different grains 320a-b and different sub-arrays 318a-n in the same bank 208.

Although the preceding discussion describes a memory allocation approach across different grains of memory, one skilled in the art will appreciate that this memory allocation approach may also be applied to different banks, with each data structure beginning in a different bank as opposed to different grains. Moreover, one skilled in the art will appreciate that one or more of the operations described above as being performed or initiated by a DRAM controller may instead be performed by a host processor.

In view of the explanations set forth above, readers will recognize that the benefits of allocating memory for processing-in-memory (PIM) devices include improved performance of a computing system by reducing row activation penalties for processing-in-memory operations acting across multiple data structures without sacrificing performance for reduction operations acting on the same data structure.

Exemplary implementations of the present disclosure are described largely in the context of a fully functional computer system for allocating memory for processing-in-memory (PIM) devices. Readers of skill in the art will recognize, however, that the present disclosure also can be embodied in a computer program product disposed upon computer readable storage media for use with any suitable data processing system. Such computer readable storage media can be any storage medium for machine-readable information, including magnetic media, optical media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps of the method of the disclosure as embodied in a computer program product. Persons skilled in the art will recognize also that, although some of the exemplary implementations described in this specification are oriented to software installed and executing on computer hardware, nevertheless, alternative implementations implemented as firmware or as hardware are well within the scope of the present disclosure.

The present disclosure can be a system, a method, and/or a computer program product. The computer program product can include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can include copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure can be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some implementations, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to implementations of the disclosure. It will be understood that each block of the flowchart illustrations and/or block diagrams, and combinations of blocks in the flowchart illustrations and/or block diagrams, can be implemented by computer readable program instructions.

These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein includes an article of manufacture including instructions which implement aspects of the function/act specified in the flowchart and/or block diagram block or blocks.

The computer readable program instructions can also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various implementations of the present disclosure. In this regard, each block in the flowchart or block diagrams can represent a module, segment, or portion of instructions, which includes one or more executable instructions for implementing the specified logical function(s). In some alternative implementations, the functions noted in the block can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be understood from the foregoing description that modifications and changes can be made in various implementations of the present disclosure. The descriptions in this specification are for purposes of illustration only and are not to be construed in a limiting sense. The scope of the present disclosure is limited only by the language of the following claims.

1. A method of allocating memory for processing-in-memory (PIM) devices, the method comprising:
allocating, in a first Dynamic Random Access Memory (DRAM) sub-array, a first data structure beginning in a first grain of the DRAM;
allocating, in a second DRAM sub-array, a second data structure beginning in a second grain of the DRAM; and
wherein the second DRAM sub-array is different from the first DRAM sub-array and the second grain is different from to the first grain, and wherein each of the first grain and the second grain are individually selectable via a corresponding selection line.

2. The method of claim 1, wherein the second DRAM sub-array is adjacent to the first DRAM sub-array and the second grain is adjacent to the first grain.

3. The method of claim 1, wherein each entry of the second data structure is stored in a DRAM grain adjacent to another DRAM grain storing a corresponding entry of the first data structure having a same index.

4. The method of claim 1, further comprising performing a processing-in-memory (PIM) operation based on the first data structure and the second data structure.

5. The method of claim 4, wherein performing the PIM operation comprises opening two or more DRAM rows in different grains concurrently.

6. The method of claim 1, further comprising performing a reduction operation based on the first data structure.

7. The method of claim 1, wherein allocating the first data structure comprises storing in a table, a first table entry comprising a first identifier for the first data structure and wherein allocating the second data structure comprises storing, in the table, a second table entry comprising a second identifier for the second data structure.

8. The method of claim 7, wherein the table comprises a page table or a page attribute table.

9. An apparatus for allocating memory for processing-in-memory (PIM) devices, comprising:
Dynamic Random Access Memory (DRAM);
a DRAM controller operatively coupled to the DRAM; and
a processor operatively coupled to the DRAM controller, the processor configured to:
allocate, in a first Dynamic Random Access Memory (DRAM) sub-array, a first data structure beginning in a first grain of the DRAM;
allocate, in a second DRAM sub-array, a second data structure beginning in a second grain of the DRAM; and
wherein the second DRAM sub-array is different from the first DRAM sub-array and the second grain is different from the first grain, and wherein each of the first grain and the second grain are individually selectable via a corresponding selection line.

10. The apparatus of claim 9, wherein the second DRAM sub-array is adjacent to the first DRAM sub-array and the second grain is adjacent to the first grain.

11. The apparatus of claim 9, wherein each entry of the second data structure is stored in a DRAM grain adjacent to another DRAM grain storing a corresponding entry of the first data structure having a same index.

12. The apparatus of claim 9, wherein the DRAM controller is configured to perform a processing-in-memory (PIM) operation based on the first data structure and the second data structure.

13. The apparatus of claim 12, wherein performing the PIM operation comprises opening two or more DRAM rows in different grains concurrently.

14. The apparatus of claim 9, wherein the DRAM controller is configured to perform a reduction operation based on the first data structure.

15. The apparatus of claim 9, wherein allocating the first data structure comprises storing, in a table, a first table entry comprising a first identifier for the first data structure and wherein allocating the second data structure comprises storing, in the table, a second table entry comprising a second identifier for the second data structure.

16. The apparatus of claim 15, wherein the table comprises a page table or a page attribute table.

17. A computer program product disposed upon a non-transitory computer readable medium, the computer program product comprising computer program instructions for allocating memory for processing-in-memory (PIM) devices that, when executed, cause a computer system to:
allocate, in a first Dynamic Random Access Memory (DRAM) sub-array, a first data structure beginning in a first grain of the DRAM;
allocate, in a second DRAM sub-array, a second data structure beginning in a second grain of the DRAM; and
wherein the second DRAM sub-array is different from the first DRAM sub-array and the second grain is different from the first grain, and wherein each of the first grain and the second grain are individually selectable via a corresponding selection line.

18. The computer program product of claim 17, wherein each entry of the second data structure is stored in a DRAM grain adjacent to another DRAM grain storing a corresponding entry of the first data structure having a same index.

19. The computer program product of claim 17, wherein the computer program instructions, when executed further cause the computer system to perform a processing-in-memory (PIM) operation based on the first data structure and the second data structure.

20. The computer program product of claim 19, wherein performing the PIM operation comprises opening two or more DRAM rows in different grains concurrently.
